(19) United States
(12) Patent Application Publication
(10) Pub. No.: US 2006/0054929 A1
(43) Pub. Date: Mar. 16, 2006

(54) Semiconductor device

(76) Inventors: Tatsuo Nakayama, Tokyo (JP); Yuji Ando, Tokyo (JP); Hironobu Miyamoto, Tokyo (JP); Kensuke Kasahara, Tokyo (JP); Yasuhiro Okamoto, Tokyo (JP); Masaaki Kuzuhara, Tokyo (JP)

Correspondence Address: MCGINN INTELLECTUAL PROPERTY LAW GROUP, PLLC, 8321 OLD COURTHOUSE ROAD, SUITE 200, VIENNA, VA, 22182-3817, US

(21) Appl. No.: 10/515,886

(22) Filed: Nov. 29, 2004

(30) Foreign Application Priority Data
May 21, 2003 (WO) PCT/JP03/06315
May 31, 2002 (JP) 2002-158965

(51) Int. Cl. H01L 31/109

(52) U.S. Cl. 257/197

(57) ABSTRACT

A semiconductor device includes, on a substrate (101), a buffer layer (102), and an channel layer (104), consisting essentially of semiconductor of a wultzite compound of group III-V, having a (0001) plane as a principal plane. The channel layer is subjected to compressive strain. A carrier supplying layer (103) is interposed between the channel layer (104) and the buffer layer (102). The carrier supplying layer (103) consists essentially of semiconductor of a wultzite compound of group III-V as a main component. N-type impurities are doped into the entire or part of the carrier supplying layer (103).

### FIELD OF THE INVENTION

This invention relates to a semiconductor device having a hetero junction field effect transistor and, more particularly, to a semiconductor device in which Iₘₐₓ may be increased without increasing the Al proportion or the film thickness.

### BACKGROUND OF THE INVENTION

In an AlGaN/GaN based hetero junction field effect transistor (HJFET) structure, there is an AlGaN/InGaN/GaN structure, having an InGaN layer, as an channel layer (carrier drift layer). With the AlGaN/InGaN/GaN structure, conduction band discontinuity (ΔE_{c}) on the AlGaN/InGaN hetero interface is larger than ΔE_{c} in the AlGaN/GaN hetero boundary. From this, it has been expected, in the AlGaN/InGaN/GaN structure, as in the conventional GaAs-based HJFET structure (AlGaAs/InGaAs/GaAs structure), that increase the maximum current (Iₘₐₓ) would increase without increasing the proportion of Al in the composition (x in AlₓGa₁₋ₓAs) or the film thickness.

On the other hand, there is disclosed in, for example, the JP Patent Kokai Publication No. JP-A-4-241430, a technique wherein impurity, such as Si, is doped to a carrier drift layer or to the substrate side of the carrier drift layer, to raise the two-dimensional electron gas concentration, in order to increase the Iₘₐₓ in the GaAs based HJFET.

FIG. 6 is a schematic partial cross-sectional view showing the structure of a field effect transistor disclosed in the Japanese Patent Kokai Publication No. JP-A-4-241430. In the structure of this field effect transistor, an AlInAs layer 1002 with a film thickness of 1 μm, an InGaAs layer 1003 with a film thickness of 10 μm, an Si+InGaAs layer 1004 doped with Si with 2×10¹⁸ cm⁻³ with a film thickness of 10 nm, an InGaAs layer 1005 with a film thickness of 10 nm, and an AlInAs layer 1006, with a film thickness of 20 nm, are layered in this order on an InP semiconductor substrate 1001.

Since the field effect transistor has the Si+InGaAs layer 1004, comprising InGaAs of the same composition as the InGaAs layer 1005, doped with Si, it is possible to increase the concentration of electrons drifting through the InGaAs layers 1003 to 1005 (channel layer or electron drift layer).

However, with the conventional AlGaN/InGaN/GaN based HJFET, piezo charges by electrical polarization are generated, due to compressive strain, applied to the InGaN layer, with the conduction band energy of the InGaN/GaN hetero interface becoming high. Since the critical film thickness of InGaN against GaN is thin, the well width becomes effectively narrow, so that electrons confined to the AlGaN/InGaN interface leak to the GaN side, with the result that the two-dimensional electron gas concentration cannot be increased, and hence Iₘₐₓ is not increased.

With the conventional GaAs-based HJFET, the two-dimensional electron gas concentration can be raised, however, since there is the Si+InGaAs layer 1004, doped with positively charged Si, in a mid portion of the same channel layer (1003 to 1005 of FIG. 6), there is raised a problem that the carrier (electron) mobility is lowered due to Coulomb scattering of the Si+InGaAs layer.

It is a primary object of the present invention to provide a semiconductor device in which Iₘₐₓ may be increased without increasing the proportion of Al in the composition or the film thickness.

It is a second object of the present invention to provide a semiconductor device in which mobility is not lowered.

### SUMMARY OF THE DISCLOSURE

In a first aspect, the present invention provides a semiconductor device comprising, on a substrate, a buffer layer, and an channel layer (or active layer), consisting essentially of semiconductor of a wultzite compound of group III-V, and having, as a principal plane, a plane on which piezo effect is produced, the channel layer being subjected to compressive strain;

the semiconductor device further comprising:

a carrier supplying layer interposed between the channel layer and the buffer layer so as to supply carriers to the channel layer; the carrier supplying layer being disposed on a (000-1) plane side of the channel layer where negative charges are induced by piezo effect;

the carriers being accumulated in the vicinity of a (0001) plane of the channel layer.

In a second aspect, the present invention provides a semiconductor device comprising, on a substrate, a buffer layer, and an channel layer, consisting essentially of semiconductor of a wultzite compound of group III-V, and having, as a principal plane, a plane on which piezo effect is produced, the channel layer being subjected to compressive strain;

the semiconductor device further comprising:

a carrier supplying layer interposed between the channel layer and the buffer layer so as to supply carriers to the channel layer; the carrier supplying layer being disposed on a (000-1) plane side of the channel layer where negative charges are induced by piezo effect, the carrier supplying layer being charged to positive polarity;

the carriers being accumulated in the vicinity of a (000-1) plane of the channel layer.

In a third aspect, the present invention provides a semiconductor device comprising, on a substrate, a buffer layer, and an channel layer, consisting essentially of semiconductor of a wultzite compound of group III-V, and having, as a principal plane, a plane on which piezo effect is produced, the channel layer being subjected to compressive strain;

the semiconductor device further comprising:

a carrier supplying layer interposed between the channel layer and the buffer layer so as to supply carriers to the channel layer, the carrier supplying layer being disposed on a (000-1) plane side of the channel layer where negative charges are induced by piezo effect, the carrier supplying layer consisting essentially of semiconductor of a wultzite compound of group III-V;

part or entire of the carrier supplying layer being doped with n-type impurities;

the carriers being accumulated in the vicinity of a (0001) plane of the channel layer.

In a fourth aspect, the present invention provides a semiconductor device comprising, on a substrate, a buffer layer, and an channel layer, consisting essentially of semiconductor of a wultzite compound of group III-V, and having, as a principal plane, a plane on which piezo effect is produced, the channel layer being subjected to compressive strain;

the semiconductor device further comprising:

a carrier supplying layer interposed between the channel layer and the buffer layer so as to supply carriers to the channel layer; the carrier supplying layer being of n-type and disposed on a (000-1) plane side of the channel layer where negative charges are induced by piezo effect;

the carriers being accumulated in the vicinity of a (0001) plane of the channel layer.

In the semiconductor device of the present invention, the surface where the piezo electric effect is produced is inclined by an angle not less than 0 degrees to not larger than 55 degrees in an arbitrary direction with respect to the (0001) plane, and preferably by an angle not less than 0 degrees to not larger than 11 degrees in an arbitrary direction with respect to the (0001) plane.

In a fifth aspect, the present invention provides a semiconductor device comprising, on a substrate, a buffer layer, and an channel layer, consisting essentially of semiconductor of a wultzite compound of group III-V, having a (0001) plane as a principal plane; the semiconductor device further comprising:

a carrier supplying layer interposed between the channel layer and the buffer layer so as to supply carriers to the channel layer; the carrier supplying layer being of n-type and disposed on a (000-1) plane side of the channel layer where negative charges are induced by piezo effect;

the carriers being accumulated in the vicinity of a (0001) plane of the channel layer in the channel layer.

In a sixth aspect, the present invention provides a semiconductor device comprising, on a substrate, a buffer layer, and an channel layer, consisting essentially of semiconductor of a wultzite compound of group III-V, having a (0001) plane as a principal plane, the channel layer being subjected to compressive strain; the semiconductor device further comprising:

a carrier supplying layer interposed between the channel layer and the buffer layer so as to supply carriers to the channel layer; the carrier supplying layer being disposed on a (000-1) plane side of the channel layer where negative charges are induced by the piezo effect, the carrier supplying layer being charged to positive polarity;

the carriers being accumulated in the vicinity of a (0001) plane of the channel layer.

In a seventh aspect, the present invention provides a buffer layer, and an channel layer, consisting essentially of semiconductor of a wultzite compound of group III-V, having a (0001) plane as a principal plane, the channel layer being subjected to compressive strain;

the semiconductor device further comprising:

a carrier supplying layer interposed between the channel layer and the buffer layer so as to supply carriers to the channel layer; the carrier supplying layer being disposed on a (000-1) plane side of the channel layer where negative charges are induced by piezo effect and consisting essentially of semiconductor of a wultzite compound of group III-V as a main component;

n-type impurities being doped to the entire or part of the carrier supplying layer;

the carriers being accumulated in the vicinity of a (0001) plane of the channel layer.

In an eighth aspect, the present invention provides a semiconductor device comprising, on a substrate, a buffer layer, and an channel layer, consisting essentially of semiconductor of a wultzite compound of group III-V, and having, as a principal plane, a plane on which piezo effect is produced, the channel layer being subjected to compressive strain;

the semiconductor device further comprising:

a carrier supplying layer interposed between the channel layer and the buffer layer so as to supply carriers to the channel layer; the carrier supplying layer being disposed on a (000-1) plane side of the channel layer where negative charges are induced by piezo effect, and consisting essentially of semiconductor of a wultzite compound of group III-V; the carrier supplying layer being of n-type;

the carriers being accumulated in the vicinity of a (0001) plane of the channel layer.

In the semiconductor devices according to the present invention, it is preferred that both of the channel layer and the carrier supplying layer consist essentially of InₓGa₁₋ₓN (0≦x≦1).

In the semiconductor devices according to the present invention, it is preferred that the carrier supplying layer is subjected to a compressive strain smaller than that of the channel layer.

In the semiconductor devices according to the present invention, the channel layer preferably consists essentially of InₐGa₁₋ₐN (0<a≦1), and the carrier supplying layer consists essentially of In_{b}Ga_{1-b}N (0≦b<a).

In the semiconductor devices according to the present invention, a second carrier supplying layer is preferably formed on the channel layer, with the second carrier supplying layer having a electron affinity smaller than that of the (first) carrier supplying layer.

In the semiconductor devices according to the present invention, the second carrier supplying layer preferably consists essentially of Al_{c}Ga_{1-c}N (0<c≦1).

In the semiconductor devices according to the present invention, the buffer layer is thickest in film thickness among plural layers formed on the substrate and consists essentially of Al_{y}Ga_{1-y}N (0<y≦1). Preferably, the channel layer consists essentially of GaN, and the carrier supplying layer consists essentially of Al_{z}Ga_{1-z}N (0<z<y).

In the semiconductor devices according to the present invention, the thickness of the carrier supplying layer is preferably not larger than the critical film thickness of a layer thickest in film thickness among plural layers formed on the substrate.

In the semiconductor devices according to the present invention, a spacer layer is preferably interposed between the channel layer and the second carrier supplying layer. The spacer layer preferably consists essentially of a strain-free wultzite group III-V compound semiconductor.

In the semiconductor devices according to the present invention, a source electrode and a drain electrode are preferably formed on the second carrier supplying layer, and a gate electrode is preferably formed in a region of the carrier supplying layer intermediate between the source electrode and the drain electrode.

### BRIEF DESCRIPTION OF THE DRAWINGS

FIG. 1 is a schematic partial cross-sectional view showing the structure of a semiconductor device according to a first Example of the present invention.

FIG. 2 is a schematic partial cross-sectional view showing the structure of a semiconductor device according to a second Example of the present invention.

FIGS. 3A and 3B are schematic views for illustrating the operation of the present invention.

FIG. 4 is a schematic view showing the crystal structure of a wultzite group III-V compound semiconductor.

FIG. 5 is a graph schematically showing the relationship between the depth, and the electron gas concentration and the conduction band (in terms of potential), respectively, in a semiconductor device according to an embodiment of the present invention.

FIG. 6 is a schematic cross-sectional view of an example of a conventional field effect transistor.

FIG. 7 is a graph schematically showing the relationship between the depth of an channel layer, and the electron gas concentration and the conduction band (in terms of potential) in the example of a conventional field effect transistor, respectively.

### PREFERRED EMBODIMENTS OF THE INVENTION

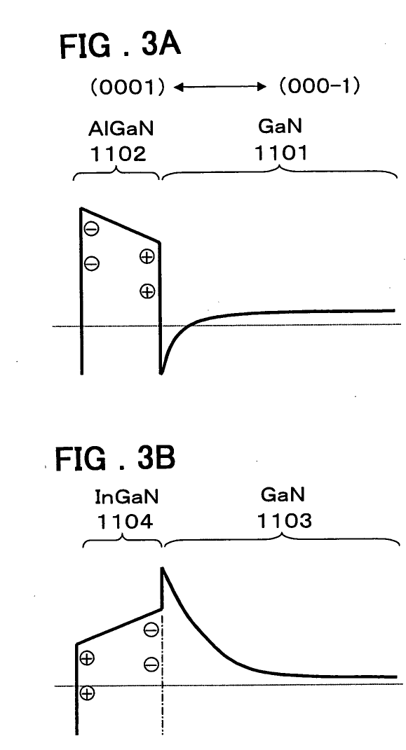

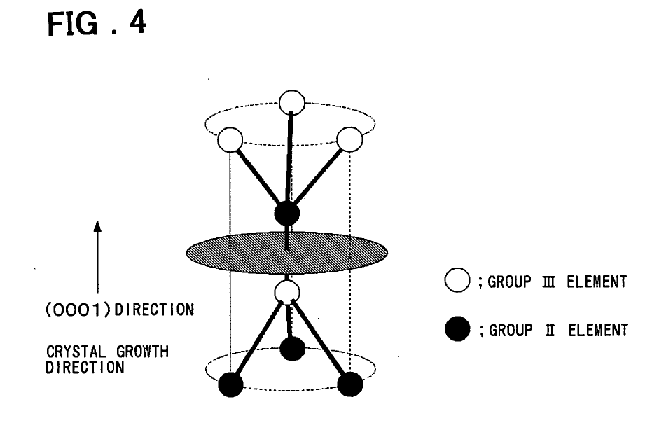

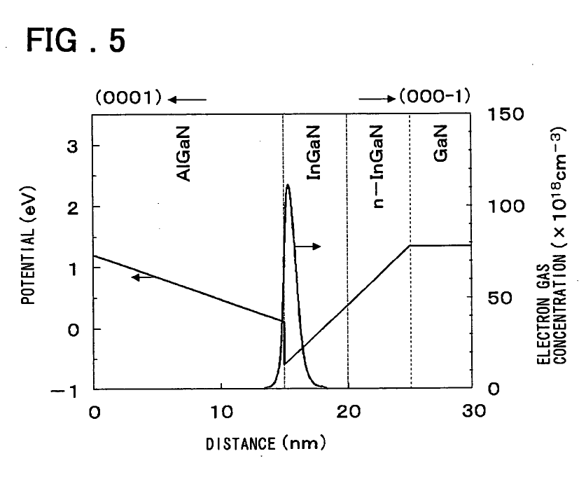

Referring to the drawings, certain preferred embodiments of the present invention are explained in detail. FIGS. 3A and 3B are schematic views for illustrating the operation of the present invention. FIG. 4 is a schematic view showing the crystal structure of a semiconductor of compound of wultzite group III-V elements, termed herein as “wultzite group III-V compound semiconductor”. FIG. 5 is a graph schematically showing the relationship between the depth, and the electron gas concentration and the conduction band, respectively, in a semiconductor device according to an embodiment of the present invention.

As a basic principle, the wultzite group III-V compound semiconductor (GaN-based semiconductor) undergoes electric polarization, by elastic lattice oscillation due to crystal strain, thus producing the piezo-effect in which the electrical potential is formed within the crystal. For example, if an AlGaN layer 1102, having a lattice constant smaller than that of the GaN layer, is formed on a GaN layer 1101, having a (0001) plane as the principal plane, positive charges are generated on the side of the AlGaN/GaN hetero interface (the side of the (000-1) plane of the AlGaN layer), whilst negative charges are generated on the opposite side (on the side of the (0001) plane of the AlGaN layer), as shown in FIG. 3A. If conversely an InGaN layer 1104, having a lattice constant larger than that of the GaN layer 1103, is formed on a GaN layer 1103, having a (0001) plane as the principal plane, negative charges are generated on the side of the InGaN/GaN hetero interface (the (000-1) plane side of the InGaN layer), whilst positive charges are generated on the opposite side (on the (0001) plane side of the InGaN layer), as shown in FIG. 3B. As for the orientation of the crystal planes, reference may be had to FIG. 4.

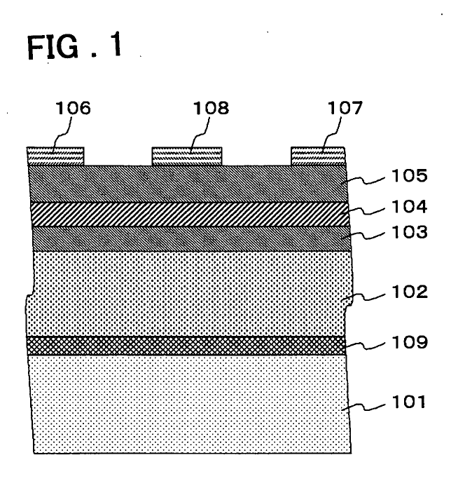

The semiconductor device of the present invention includes an channel layer, formed of a wultzite group III-V compound semiconductor, suffering compressive strain, such as InGaN (see 104 of FIG. 1), and an n type semiconductor layer, formed of a wultzite group III-V compound semiconductor, such as InGaN, doped with an n type impurity (Si), providing a carrier (electrons) to the (000-1) plane side (on the substrate side) of the channel layer where negative charges are generated (see 103 of FIG. 1).

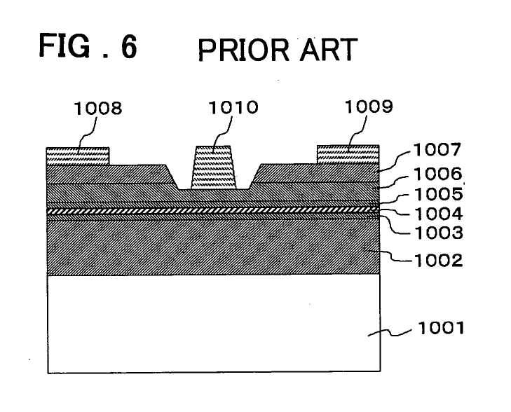

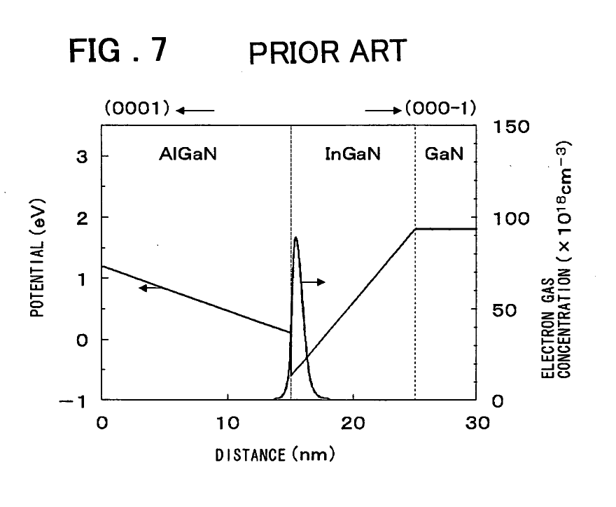

With the use of this structure, it is possible to accumulate electrons, supplied from the n-type impurity (Si), on the (0001) plane side of the operation layer (InGaN layer) where positive charges are generated, such that it is possible to increase the electron gas concentration (by approximately 20 to 30%) as compared to that with the conventional technique devoid of the n-type semiconductor layer (AlGaN/InGaN/GaN based HJFET) (compare FIG. 5 to FIG. 7).

Moreover, since the n-type impurity (Si), which has donated electrons and has thereby been charged to the positive polarity, is spatially separated from released electrons, it is possible to reduce the effect of Coulomb scattering caused by the positively charged n-type impurity (Si) to achieve a superior electron transporting characteristic (mobility). Since negative electrical charges are generated on (000-1) plane side of the channel layer (InGaN layer), it is possible to suppress penetrating towards a buffer layer (GaN layer) of the electrons confined in the interface between the carrier supplying layer and the channel layer (AlGaN/InGaN interface). That is, since the leakage of electrons to the buffer layer (GaN layer) may be suppressed, as electrons are effectively supplied to the channel layer (InGaN layer), it is possible to achieve marked effects in increasing the amount of the current at the time of high-voltage operation in the field effect transistor.

In addition, since the electrons may be supplied to the channel layer (InGaN layer), independently of electron supply from the surface side carrier supplying layer (AlGaN layer), electrons may be accumulated in the channel layer (InGaN layer) to suppress the sheet resistance from increasing, even though the film thickness of the carrier supplying layer=Schottky layer (AlGaN layer) in the structure of the type “metal (ohmic metal)/carrier supplying layer=Schottky layer (AlGaN layer)/channel layer (InGaN layer)” is reduced for the purpose of reducing the tunnel resistance in the ohmic contact.

Referring to the drawings, a first Example of the present invention is hereinafter explained. FIG. 1 is a schematic partial cross-sectional view showing the structure of a semiconductor device according to a first Example of the present invention.

In this semiconductor device, pertinent to a field effect transistor, includes a substrate 101, on which a buffer layer 102, a first carrier supplying layer 103, an channel layer 104 and a second carrier supplying layer 105 are formed in this order. A source electrode 106 and a drain electrode 107, having ohmic contact with the second carrier supplying layer 105, are then formed on the second carrier supplying layer 105. A gate electrode 108, having Schottky contact with the second carrier supplying layer 105, then is formed in an area of the second carrier supplying layer 105 between the source electrode 106 and the drain electrode 107. In this fashion completes a field effect transistor is formulated.

For the substrate 101, group III nitride semiconductors, such as GaN, AlGaN or AlN, for example, are used, in addition to sapphire or silicon carbide. The surface of the substrate 101, on an upper layer of which crystals are caused to grow, is preferably a c-plane ((0001) plane). It is however sufficient if the surface permits the GaN-based semiconductor to be oriented along the C-axis and grown to produce the piezo effect. The surface may be inclined up to approximately 55 degrees in an arbitrary direction. However, since optimum crystal property cannot be obtained with a large angle of inclination, the surface is preferably inclined at an angle within 10 degrees in an optional orientation.

The buffer layer 102 relaxes the strain by the lattice non-matching between the substrate 101 and the carrier supplying layer 103, and is the thickest layer among the layers formed on the substrate 101. The buffer layer 102 is formed of a GaN based semiconductor, such as GaN, InN, AlN or combinations of two or three of these compounds. A nuclei forming layer 109, formed of a GaN based semiconductor, such as GaN, InN, AlN or combinations of two or three of these compounds, may be sandwiched between the substrate 101 and the buffer layer 102 for forming the buffer layer 102. The buffer layer 102 may suitably be added by (doped with) an impurity, such as n-type impurity, e.g. Si, S or Se, or a p-type impurity, e.g. Be, C of Mg.

The first carrier supplying layer 103 is formed of a substance or a composition, having a lattice constant larger than that of the buffer layer 102, and which is subjected to compressive strain. The first carrier supplying layer 103 is formed e.g. of a GaN based semiconductor, such as GaN, InN, AlN or combinations of two or three of these compounds. Moreover, the first carrier supplying layer 103 may suitably be added by (doped with) an impurity. The impurity used may, for example, be an n-type impurity, such as Si, S or Se. The first carrier supplying layer 103 may be added (of a desired film thickness. The lattice constant of the first carrier supplying layer 103 differs from that of the buffer layer 102, and hence is preferably not larger than the critical film thickness at which translocation may be produced.

The channel layer 104, also termed a carrier drift layer, has a lattice constant larger than that of the first carrier supplying layer 103, and is formed of a material or a composition which is subjected to compressive strain (or stress) more strongly than the first carrier supplying layer 103. However, if the strain (stress) is excessively strong, the critical film thickness becomes thin, such that the channel layer ceases to operate as a carrier drift layer. Hence, the difference of the lattice constant of the channel layer from that of the buffer layer 102 is preferably not larger than 3%. The channel layer 104 is formed of a GaN based (type) semiconductor, such as GaN, InN, AlN or combinations of two or three of these compounds. The channel layer 104 may suitably be doped with an impurity. The impurity may be enumerated by n-type impurity, such as Si, S or Se, or p-type impurity, such as Be, C or Mg. However, if the impurity concentration in the channel layer 104 is high, electron mobility is lowered due to Coulomb scattering. Hence, the impurity concentration in the channel layer 104 is preferably not larger than 1×10¹⁷ cm⁻³. The film thickness of the channel layer 104 may be of any suitable desired value. However, since the lattice constant of the channel layer 104 differs from that of the buffer layer 102, the film thickness of the channel layer 104 is preferably not larger than the critical film thickness for which the translocation is produced.

The second carrier supplying layer 105 is formed of a material or composition exhibiting electron affinity lower than that of the material of the first carrier supplying layer 103. Specifically, the second carrier supplying layer 105 is formed of a GaN based semiconductor, such as GaN, InN, AlN or combinations of two or three of these compounds. Moreover, the second carrier supplying layer 105 may be doped with n-type impurities, such as Si, S or Se, or p-type impurities, such as Be, C or Mg. The film thickness of the second carrier supplying layer 105 may be of any suitable desired value. However, since the lattice constant of the second carrier supplying layer 105 differs from that of the buffer layer 102, the film thickness of the second carrier supplying layer 105 is preferably not larger than the critical film thickness at which the translocation is produced.

The source electrode 106 and the drain electrode 107 are formed of metal having ohmic contact with the second carrier supplying layer 105. For example, such metals as W, Mo, Si, Ti, Pt, Al or Au etc. may be used. In addition, the source electrode 106 and the drain electrode 107 may be formed by laminating plural sorts of the above metals together.

The gate electrode 108 is formed of a metal, having Schottky contact with the second carrier supplying layer 105, such as W, Mo, Si, Ti, Pt, Al or Au etc. The gate electrode 108 may be formed by laminating plural sorts of the above metals together.

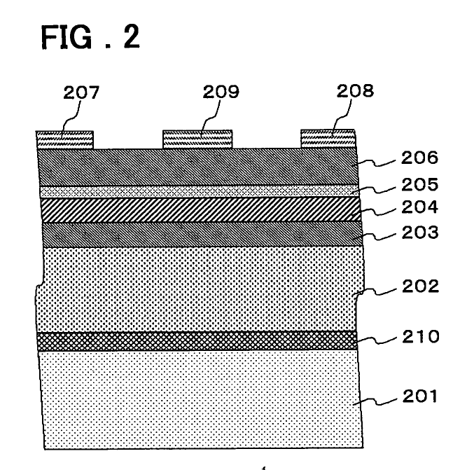

Referring to the drawings, a second Example of the present invention is hereinafter explained. FIG. 2 is a schematic partial cross-sectional view showing the structure of a semiconductor device according to a second Example of the present invention.

In this semiconductor device, pertinent to a field effect transistor, includes a substrate 201, on which a buffer layer 202, a first carrier supplying layer 203, an channel layer 204, a spacer layer 205 and a second carrier supplying layer 206 are formed in this order. A source electrode 207 and a drain electrode 208, having ohmic contact with the second carrier supplying layer 206, are then formed on the second carrier supplying layer 206. A gate electrode 209, having Schottky contact with the second carrier supplying layer 206, then is formed in an area of the second carrier supplying layer 206 between the source electrode 207 and the drain electrode 208. This completes a field effect transistor.

The components of the field effect transistor, other than the spacer layer 205, namely the substrate 201, buffer layer 202, first carrier supplying layer 203, carrier drift layer (channel layer 204), second carrier supplying layer 206, source electrode 207, drain electrode 208 and the gate electrode 209, are similar to the corresponding components explained in the above-described first Example. As for these components, reference is made to the explanation in the first Example.

The spacer layer 205 is formed of a GaN based (or type) semiconductor, such as GaN, InN, AlN or combinations of two or three of these compounds. It is noted that, since the spacer layer 205 forms a smooth hetero interface, at the time of the film formation, the spacer layer 205 is preferably formed of a material or composition having a lattice constant equal to that of the semiconductor material of the buffer layer 202, or having a lattice constant intermediate between the lattice constant of the carrier drift layer 204 and that of the second carrier supplying layer 206.

### EXAMPLES

A semiconductor device according to a first Example of the present invention is now explained. As for the structure of the first Example of the semiconductor device, reference is made to FIG. 1.

The method for producing the first Example of the semiconductor device is now explained. As the substrate 101, a silicon carbide (SiC) substrate, having a c-plane ((0001) plane) as a crystal growth surface, is used. An AlN layer, as the nuclei forming layer 109, a GaN layer (film thickness: 1500 nm), as a buffer layer 102, an InGaN layer, added by (doped with) Si (In_{0.1}Ga_{0.9}N, film thickness: 5 nm, and an amount of Si addition of 1×10¹⁹ cm⁻³), as the first carrier supplying layer 103, an InGaN layer, doped with Si (In_{0.1}Ga_{0.9}N, film thickness of 5 nm), as the channel layer 104, and an AlGaN layer (Al_{0.3}Ga_{0.7}N, film thickness of 20 nm), as the second carrier supplying layer 105, are formed in this order on the substrate by organic metal vapor phase epitaxial (MOVPE) method. The film forming conditions for these layers are the usual conditions (conventional conditions). On the second carrier supplying layer 105, a resist pattern for forming a source electrode and a drain electrode is then formed on the second carrier supplying layer 105. Then, Ti/Al (with the film thickness of a Ti layer of 10 nm and that of an Al layer of 200 nm), as a first metal, is deposited by electron gun vapor deposition, followed by lift-off. The resulting product is lamp-annealed (650° C., 30 sec) to form the source electrode 106 and the drain electrode 107. A resist pattern for forming a gate electrode is then formed on the second carrier supplying layer 105, source electrode 106 and on the drain electrode 107. Then, Ni/Au (with the film thickness of a Ni layer of 10 nm and that of an Au layer of 200 nm), as a second metal, is deposited by electron gun vapor deposition, followed by lift-off, to form the gate electrode 108. In the above fashion a field-effect transistor is formulated.

In the above-described structure, since the first carrier supplying layer 103 (Si+InGaN layer) 103 and the channel layer (InGa layer) 104 are subjected to compressive strain (stress), an electrical field is generated, under the piezo effect, in a direction of uplifting the conduction band on the interface between the first carrier supplying layer (Si+InGaN layer) 103 and the buffer layer (GaN layer) 102 towards a high energy side. Consequently, (the potential of) the first carrier supplying layer (Si+InGaN layer) 103 is higher (in potential) than the Fermi level, so that Si added to the first carrier supplying layer (Si+InGaN layer) 103 is activated by approximately 100% to supply electrons to the channel layer (InGaN layer) 104. The result is that the two-dimensional electron gas concentration is effectively increased to increase Iₘₐₓ. On the other hand, since the first carrier supplying layer (Si+InGaN layer) 103, containing Si which donated electrons and which thereby are charged positively, is distinct (i.e., in a different layer) from the channel layer (InGaN layer) 104 which has now accumulated electrons, it is possible to reduce the effect of Coulomb scattering due to positively charged Si atoms in the first carrier supplying layer (Si+InGaN layer) 103 as well as to reduce the lowering in the mobility.

Although no impurities are added to the second carrier drift layer (InGaN layer) 105, the holes at N atoms in the buffer layer (GaN) 102 act similarly to the n-type impurities to emit electrons, the density of which is approximately 5×10¹⁶ cm⁻³.

A semiconductor device according to a second Example of the present invention is now explained. As for the structure of the second Example of the semiconductor device, reference is made to FIG. 1.

The method for producing the second Example of the semiconductor device is now explained. As the substrate 101, a silicon carbide (SiC) substrate, having a c-plane ((0001) plane) as a crystal growth surface, is used. An AlN layer, as the nuclei forming layer 109, an AlGaN layer (Al_{0.2}Ga_{0.8}N, film thickness: 1500 nm), as a buffer layer 102, a GaN layer, doped with Si (film thickness: 5 nm, an amount of Si addition of 1×10¹⁹ cm⁻³), as the first carrier supplying layer 103, a GaN layer (film thickness of 15 nm), as the channel layer 104 and an AlGaN layer (Al_{0.4}Ga_{0.6}N, film thickness of 20 nm), as the second carrier supplying layer 105, are formed in this order on the substrate by organic metal vapor phase epitaxial (MOVPE) method. The film forming conditions for these layers are the usual conditions (conventional conditions). On the second carrier supplying layer 105, a resist pattern for forming a source electrode and a drain electrode is then formed on the second carrier supplying layer 105. Then, Ti/Al (with a film thickness of a Ti layer of 10 nm and that of an Al layer of 200 nm), as a first metal, is deposited by electron gun vapor deposition, followed by lift-off. The resulting product is lamp-annealed (650° C., 30 sec) to form the source electrode 106 and the drain electrode 107. A resist pattern for forming a gate electrode is then formed on the second carrier supplying layer 105, source electrode 106 and on the drain electrode 107. Then, Ni/Au (with a film thickness of a Ni layer of 10 nm and that of an Au layer of 200 nm), as a second metal, is deposited by electron gun vapor deposition, followed by lift-off, to form the gate electrode 108. The above completes a field-effect transistor.

In the above-described structure, since the first carrier supplying layer 103 (Si+GaN layer) 103 and the channel layer (GaN layer) 104 are subjected to compressive strain (stress), an electrical field is generated, under the piezo effect, in a direction of uplifting a conduction band on the interface between the first carrier supplying layer (Si+GaN layer) 103 and the buffer layer (AlGaN layer) 102 towards a high energy side. Consequently, the first carrier supplying layer (Si+GaN layer) 103 is higher (in potential) than the Fermi level so that Si added to the first carrier supplying layer (Si+GaN layer) 103 is activated by approximately 100% to supply electrons to the channel layer (GaN layer) 104. The result is that the two-dimensional electron gas concentration is effectively increased to increase Iₘₐₓ. On the other hand, since the first carrier supplying layer (Si+GaN layer) 103, containing Si which donated electrons and which thereby are charged positively, is distinct from the channel layer (GaN layer) 104 which has now accumulated electrons, it is possible to reduce the effect of Coulomb scattering due to positively charged Si (atoms) in the first carrier supplying layer (Si+GaN layer) 103 as well as to reduce the lowering in the mobility.

A semiconductor device according to a third Example of the present invention is now explained. As for the structure of the third Example of the semiconductor device, reference is made to FIG. 1.

The method for producing the third Example of the semiconductor device is now explained. As the substrate 101, a silicon carbide (SiC) substrate, having a c-plane ((0001) plane) as a crystal growth surface, is used. An AlN layer, as the nuclei forming layer 109, a GaN layer (film thickness: 1500 nm), as a buffer layer 102, an InGaN layer, doped with Si (In_{0.1}Ga_{0.9}N, film thickness: 5 nm, an amount of Si addition of 1×10¹⁹ cm⁻³), as the first carrier supplying layer 103, an InGaN layer (In_{0.15}Ga_{0.85}N, film thickness of 5 nm), as the channel layer 104, and an AlGaN layer (Al_{0.3}Ga_{0.7}N, film thickness of 20 nm), as the second carrier supplying layer 105, are formed in this order on the substrate by organic metal vapor phase epitaxial (MOVPE) method. The film forming conditions for these layers are the usual conditions (conventional conditions). On the second carrier supplying layer 105, a resist pattern for forming a source electrode and a drain electrode is then formed on the second carrier supplying layer 105. Then, Ti/Al (with the film thickness of a Ti layer of 10 nm and that of an Al layer of 200 nm), as a first metal, is deposited by electron gun vapor deposition, followed by lift-off. The resulting product is lamp-annealed (650° C., 30 sec) to form the source electrode 106 and the drain electrode 107. A resist pattern for forming a gate electrode is then formed on the second carrier supplying layer 105, source electrode 106 and on the drain electrode 107. Then, Ni/Au (with the film thickness of a Ni layer of 10 nm and that of an Au layer of 200 nm), as a second metal, is deposited by electron gun vapor deposition, followed by lift-off, to form the gate electrode 108. The above completes a field-effect transistor.

In the above-described structure, since the first carrier supplying layer 103 (Si+InGaN layer) 103 and the channel layer (InGaN layer) 104 are subjected to compressive strain, an electrical field is generated, under the piezo effect, in a direction of uplifting a conduction band on the interface between the first carrier supplying layer (Si+InGaN layer) 103 and the buffer layer (GaN layer) 102 towards a high energy side. Since the amount of strain of the channel layer (InGaN layer) 104 is large and the piezo effect operates strongly, an electrical field is generated in a direction of uplifting the conduction band of the first carrier supplying layer (Si+InGaN layer) 103 to a higher (in potential) energy side. Consequently, the first carrier supplying layer (Si+InGaN layer) 103 is higher (in potential) than the Fermi level so that Si added to the first carrier supplying layer (Si+InGaN layer) 103 is activated by approximately 100% to supply electrons to the channel layer (InGaN layer) 104. The result is that the two-dimensional electron gas concentration is effectively increased to increase Iₘₐₓ. On the other hand, since the first carrier supplying layer (Si+InGaN layer) 103, containing Si which donated electrons and which thereby are charged positively, is distinct from the channel layer (InGaN layer) 104 which has now accumulated electrons, it is possible to reduce the effect of Coulomb scattering due to positively charged Si (atoms) in the first carrier supplying layer (Si+InGaN layer) 103 as well as to reduce the lowering in the mobility.

A semiconductor device according to a fourth Example of the present invention is now explained. As for the structure of the fourth Example of the semiconductor device, reference is made to FIG. 1.

The method for producing the fourth Example of the semiconductor device is now explained. As the substrate 101, a silicon carbide (SiC) substrate, having a c-plane ((0001) plane) as a crystal growth surface, is used. An AlN layer, as the core forming layer 109, an AlGaN layer (Al_{0.2}Ga_{0.8}N, film thickness: 1500 nm), as a buffer layer 102, a GaN layer, doped with Si (film thickness: 5 nm, and an amount of Si addition of 1×10¹⁹ cm⁻³), as the first carrier supplying layer 103, an InGaN layer, doped with Si (In_{0.1}Ga_{0.9}N, film thickness of 5 nm), as the channel layer 104 and an AlGaN layer (Al_{0.4}Ga_{0.6}N, film thickness of 20 nm), as the second carrier supplying layer 105, are formed in this order on the substrate by organic metal vapor phase epitaxial (MOVPE) method. The film forming conditions for these layers are the usual conditions (conventional conditions). On the second carrier supplying layer 105, a resist pattern for forming a source electrode and a drain electrode is then formed on the second carrier supplying layer 105. Then, Ti/Al (with the film thickness of a Ti layer of 10 nm and that of an Al layer of 200 nm), as a first metal, is deposited by electron gun vapor deposition, followed by lift-off. The resulting product is lamp-annealed (650° C., 30 sec) to form the source electrode 106 and the drain electrode 107. A resist pattern for forming a gate electrode is then formed on the second carrier supplying layer 105, source electrode 106 and on the drain electrode 107. Then, Ni/Au (with the film thickness of a Ni layer of 10 nm and that of an Au layer of 200 nm), as a second metal, is deposited by electron gun vapor deposition, followed by lift-off, to form the gate electrode 108. The above completes a field-effect transistor.

In the above-described structure, since the first carrier supplying layer (Si+GaN layer) 103 and the channel layer (InGaN layer) 104 are subjected to compressive strain, an electrical field is generated, under the piezo effect, in a direction of uplifting a conduction band on the interface between the first carrier supplying layer (Si+InGaN layer) 103 and the buffer layer (GaN layer) 102 towards a high energy side. Since the amount of strain of the channel layer (InGaN layer) 104 is large and the piezo effect operates strongly, an electrical field is generated in a direction of uplifting a conduction band of the first carrier supplying layer (Si+GaN layer) 103 to a higher energy side. Consequently, the first carrier supplying layer (Si+InGaN layer) 103 is higher (in potential) than the Fermi level, so that Si added to the first carrier supplying layer (Si+GaN layer) 103 is activated by approximately 100% to supply electrons to the channel layer (InGaN layer) 104. The result is that the two-dimensional electron gas concentration is effectively increased to increase Iₘₐₓ. On the other hand, since the first carrier supplying layer (Si+GaN layer) 103, containing Si which donated electrons and which thereby are charged positively, is distinct (i.e., in a layer different) from the channel layer (InGaN layer) 104 which has now accumulated electrons, it is possible to reduce the effect of Coulomb scattering due to positively charged Si in the first carrier supplying layer (Si+GaN layer) 103 as well as to reduce the lowering in the mobility.

A semiconductor device according to a fifth Example of the present invention is now explained. As for the structure of the fifth Example of the semiconductor device, reference is made to FIG. 2.

The method for producing the—fifth Example of the semiconductor device is now explained. As the substrate 101, a silicon carbide (SiC) substrate, having a c-plane ((0001) plane) as a crystal growth surface, is used. An AlN layer, as a core forming layer 210, a GaN layer (film thickness: 1500 nm), as a buffer layer 202, an InGaN layer, doped with Si (In_{0.1}Ga_{0.9}N, film thickness: 5 nm, an amount of Si addition of 1×10¹⁹ cm⁻³), as the first carrier supplying layer 203, an InGaN layer (In_{0.15}Ga_{0.85}N, film thickness of 5 nm), as the channel layer 204, GaN (film thickness: 2 nm) as a spacer layer 205, and an AlGaN layer (Al_{0.3}Ga_{0.7}N, film thickness of 20 nm), as the second carrier supplying layer 206, are formed in this order on the substrate by organic metal vapor phase epitaxial (MOVPE) method. The film forming conditions for these layers are the usual conditions (conventional conditions). On the second carrier supplying layer 105, a resist pattern for forming a source electrode and a drain electrode is then formed on the second carrier supplying layer 105. Then, Ti/Al (with the film thickness of a Ti layer of 10 nm and that of an Al layer of 200 nm), as a first metal, is deposited by electron gun vapor deposition, followed by lift-off. The resulting product is lamp-annealed (650° C., 30 sec) to form the source electrode 206 and the drain electrode 207. A resist pattern for forming a gate electrode is then formed on the second carrier supplying layer 205, source electrode 206 and on the drain electrode 207. Then, Ni/Au (with a film thickness of a Ni layer of 10 nm and that of an Au layer of 200 nm), as a second metal, is deposited by electron gun vapor deposition, followed by lift-off, to form the gate electrode 209. The above completes a field-effect transistor.

In the above-described structure, since the first carrier supplying layer (Si+InGaN layer) 203 and the channel layer (InGaN layer) 204 are subjected to compressive strain, an electrical field is generated, under the piezo effect, in a direction of uplifting a conduction band on the interface between the first carrier supplying layer (Si+InGaN layer) 203 and the buffer layer (GaN layer) 202 towards a high energy side. Since in particular the amount of strain of the channel layer (InGaN layer) 204 is large and the piezo effect operates strongly, an electrical field is generated in a direction of uplifting a conduction band of the first carrier supplying layer (Si+GaN layer) 203 to a higher energy side. Consequently, the first carrier supplying layer (Si+InGaN layer) 103 is higher (in potential) than the Fermi level so that Si added to the first carrier supplying layer (Si+InGaN layer) 203 is activated by approximately 100% to supply electrons to the channel layer (InGaN layer) 204. The result is that the two-dimensional electron gas concentration is effectively increased to increase Iₘₐₓ. On the other hand, since the first carrier supplying layer (Si+InGaN layer) 203, containing Si which donated electrons and which thereby are charged positively, is distinct from the channel layer (InGaN layer) 204 which has now accumulated electrons and which are charged positively, it is possible to reduce the effect of Coulomb scattering due to positively charged Si (atoms) in the first carrier supplying layer (Si+InGaN layer) 203 as well as to reduce the lowering in mobility. Moreover, since the spacer layer (GaN layer) 205 may be formed under the growth conditions intermediate between the growth conditions for the channel layer (InGaN layer) 204 and the second carrier supplying layer (AlGaN layer) 206 with appreciably different growth conditions, it is possible to form a smooth hetero interface as well as to achieve a higher mobility.

A semiconductor device according to a sixth Example of the present invention is now explained. As for the structure of the sixth Example of the semiconductor device, reference is made to FIG. 2.

The method for producing the sixth Example of the semiconductor device is now explained. As the substrate 201, a silicon carbide (SiC) substrate, having a c-plane ((0001) plane) as a crystal growth surface, is used. An AlN layer, as the nuclei forming layer 210, an AlGaN layer (Al_{0.2}Ga_{0.8}N, film thickness: 1500 nm), as a buffer layer 202, an InGaN layer, doped with Si (In_{0.05}Ga_{0.95}N, film thickness: 5 nm, an amount of Si addition of 1×10¹⁹ cm⁻³), as the first carrier supplying layer 203, an InGaN layer (In_{0.1}Ga_{0.9}N, film thickness of 7 nm), as the channel layer 204, a GaN layer (film thickness: 2 nm), as a spacer layer 205, and an AlGaN layer (Al_{0.4}Ga_{0.6}N, film thickness of 20 nm), as the second carrier supplying layer 206, are formed in this order on the substrate by organic metal vapor phase epitaxial (MOVPE) method. The film forming conditions for these layers are the usual conditions (conventional conditions). On the second carrier supplying layer 206, a resist pattern for forming a source electrode and a drain electrode is then formed on the second carrier supplying layer 206. Then, Ti/Al (with the film thickness of a Ti layer of 10 nm and that of an Al layer of 200 nm), as a first metal, is deposited by electron gun vapor deposition, followed by lift-off. The resulting product is lamp-annealed (650° C., 30 sec) to form the source electrode 206 and the drain electrode 207. A resist pattern for forming a gate electrode is then formed on the second carrier supplying layer 206, source electrode 207 and on the drain electrode 208. Then, Ni/Au (with the film thickness of a Ni layer of 10 nm and that of an Au layer of 200 nm), as a second metal, is deposited by electron gun vapor deposition, followed by lift-off, to form the gate electrode 209. The above completes a field-effect transistor.

In the above-described structure, since the first carrier supplying layer (Si+InGaN layer) 203 and the channel layer (InGaN layer) 204 are subjected to compressive strain, an electrical field is generated, under the piezo effect, in a direction of uplifting a conduction band on the interface between the first carrier supplying layer (Si+InGaN layer) 203 and the buffer layer (AlGaN layer) 202 towards a high energy side. Since the amount of strain of the channel layer (InGaN layer) 204 is large and the piezo effect operates strongly, an electrical field is generated in a direction of uplifting a conduction band of the first carrier supplying layer (Si+InGaN layer) 203 to a higher energy side. Consequently, the first carrier supplying layer (Si+InGaN layer) 203 is higher (in potential) than the Fermi level so that Si added to the first carrier supplying layer (Si+InGaN layer) 203 is activated by approximately 100% to supply electrons to the channel layer (InGaN layer) 204. The result is that the two-dimensional electron gas concentration is effectively increased to increase Iₘₐₓ. On the other hand, since the first carrier supplying layer (Si+InGaN layer) 203, containing Si which donated electrons and which thereby are charged positively, is distinct (different in layer) from the channel layer (InGaN layer) 204 which has now accumulated electrons, it is possible to reduce the effect of Coulomb scattering due to positively charged Si in the first carrier supplying layer (Si+InGaN layer) 203 as well as to reduce the lowering in the mobility. Moreover, since the spacer layer (GaN layer) 205 may be formed under the growth conditions intermediate between the growth conditions for the channel layer (InGaN layer) 204 and the second carrier supplying layer (AlGaN layer) 206 with appreciably different growth conditions, it is possible to form a smooth hetero interface as well as to achieve a higher mobility.

### INDUSTRIAL APPLICABILITY

According to the present invention, it is possible to suppress the electron leakage to the buffer layer, as electrons are effectively supplied towards the channel layer, and hence the Iₘₐₓ may be increased without increasing the proportion of Al in the composition or the film thickness. Moreover, the effect of Coulomb scattering may be decreased to realize a superior electron transporting characteristic (mobility).

In addition, electrons may be supplied to the channel layer independently of electrons supplied from the surface side second carrier supplying layer, so that electrons may be accumulated in the channel layer to suppress the sheet resistance from increasing, even though the film thickness of the second carrier supplying layer is decreased in order to decrease the tunnel resistance in ohmic contact.

It should be noted that other objects, features and aspects of the present invention will become apparent in the entire disclosure and that modifications may be done without departing the gist and scope of the present invention as disclosed herein and claimed as appended herewith.

Also it should be noted that any combination of the disclosed and/or claimed elements, matters and/or items may fall under the modifications aforementioned.

What is claimed is:

1. A semiconductor device comprising, on a substrate, a buffer layer, and an channel layer, consisting essentially of semiconductor of a wultzite compound of group III-V, and having, as a principal plane, a plane on which piezo effect is produced, said channel layer being subjected to compressive strain;
said semiconductor device further comprising:
a carrier supplying layer interposed between said channel layer and said buffer layer so as to supply carriers to said channel layer; said carrier supplying layer being disposed on a (000-1) plane side of said channel layer where negative charges are induced by piezo effect;
the carriers being accumulated in the vicinity of a (0001) plane of said channel layer.

2. A semiconductor device comprising, on a substrate, a buffer layer, and an channel layer, consisting essentially of semiconductor of a wultzite compound of group III-V, and having, as a principal plane, a plane on which piezo effect is produced, said channel layer being subjected to compressive strain;
said semiconductor device further comprising:
a carrier supplying layer interposed between said channel layer and said buffer layer so as to supply carriers to said channel layer; said carrier supplying layer being disposed on a (000-1) plane side of said channel layer where negative charges are induced by piezo effect, said carrier supplying layer being charged to positive polarity;
the carriers being accumulated in the vicinity of a (000-1) plane of said channel layer.

3. A semiconductor device comprising, on a substrate, a buffer layer, and an channel layer, consisting essentially of semiconductor of a wultzite compound of group III-V, and having, as a principal plane, a plane on which piezo effect is produced, said channel layer being subjected to compressive strain;
said semiconductor device further comprising:
a carrier supplying layer interposed between said channel layer and said buffer layer so as to supply carriers to said channel layer, said carrier supplying layer being disposed on a (000-1) plane side of said channel layer where negative charges are induced by piezo effect, said carrier supplying layer consisting essentially of semiconductor of a wultzite compound of group III-V;
part or entire of said carrier supplying layer being doped with n-type impurities;
the carriers being accumulated in the vicinity of a (0001) plane of said channel layer.

4. A semiconductor device comprising, on a substrate, a buffer layer, and an channel layer, consisting essentially of semiconductor of a wultzite compound of group III-V, and having, as a principal plane, a plane on which piezo effect is produced, said channel layer being subjected to compressive strain;
said semiconductor device further comprising:
a carrier supplying layer interposed between said channel layer and said buffer layer so as to supply carriers to said channel layer; said carrier supplying layer being of n-type and disposed on a (000-1) plane side of said channel layer where negative charges are induced by piezo effect;
the carriers being accumulated in the vicinity of a (0001) plane of said channel layer.

5. The semiconductor device as defined in claim 1 wherein said surface where the piezo electric effect is produced is inclined by an angle not less than 0 degrees to not larger than 55 degrees in an arbitrary direction with respect to the (0001) plane.

6. The semiconductor device as defined in claim 1 wherein said surface where the piezo electric effect is produced is inclined by an angle not less than 0 degrees to not larger than 11 degrees in an arbitrary direction with respect to the (0001) plane.

7. A semiconductor device comprising, on a substrate, a buffer layer, and an channel layer, consisting essentially of semiconductor of a wultzite compound of group III-V, having a (0001) plane as a principal plane; said semiconductor device further comprising:
a carrier supplying layer interposed between said channel layer and said buffer layer so as to supply carriers to said channel layer; said carrier supplying layer being of n-type and disposed on a (000-1) plane side of said channel layer where negative charges are induced by piezo effect;
the carriers being accumulated in the vicinity of a (0001) plane of said channel layer in said channel layer.

8. A semiconductor device comprising, on a substrate, a buffer layer, and an channel layer, consisting essentially of semiconductor of a wultzite compound of group III-V, having a (0001) plane as a principal plane, said channel layer being subjected to compressive strain; said semiconductor device further comprising:
a carrier supplying layer interposed between said channel layer and said buffer layer so as to supply carriers to said channel layer; said carrier supplying layer being disposed on a (000-1) plane side of said channel layer where negative charges are induced by the piezo effect, said carrier supplying layer being charged to positive polarity;
the carriers being accumulated in the vicinity of a (0001) plane of said channel layer.

9. A semiconductor device comprising, on a substrate, a buffer layer, and an channel layer, consisting essentially of semiconductor of a wultzite compound of group III-V, having a (0001) plane as a principal plane, said channel layer being subjected to compressive strain;
said semiconductor device further comprising:
a carrier supplying layer interposed between said channel layer and said buffer layer so as to supply carriers to said channel layer; said carrier supplying layer being disposed on a (000-1) plane side of said channel layer where negative charges are induced by piezo effect and consisting essentially of semiconductor of a wultzite compound of group III-V as a main component;
n-type impurities being doped to the entire or part of said carrier supplying layer;
the carriers being accumulated in the vicinity of a (0001) plane of said channel layer.

10. A semiconductor device comprising, on a substrate, a buffer layer, and an channel layer, consisting essentially of semiconductor of a wultzite compound of group III-V, and having, as a principal plane, a plane on which piezo effect is produced, said channel layer being subjected to compressive strain;
said semiconductor device further comprising:
a carrier supplying layer interposed between said channel layer and said buffer layer so as to supply carriers to said channel layer; said carrier supplying layer being disposed on a (000-1) plane side of said channel layer where negative charges are induced by piezo effect, and consisting essentially of semiconductor of a wultzite compound of group III-V; said carrier supplying layer being of n-type;
the carriers being accumulated in the vicinity of a (0001) plane of said channel layer.

11. The semiconductor device as defined in claim 1 wherein both of said channel layer and said carrier supplying layer consist essentially of InₓGa₁₋ₓN (0≦x≦1).

12. The semiconductor device as defined in claim 1 wherein said carrier supplying layer is subjected to a compressive strain smaller than that of said channel layer.

13. The semiconductor device as defined in claim 12 wherein said channel layer consists essentially of InₐGa₁₋ₐN (0<a≦1); and wherein said carrier supplying layer consists essentially of In_{b}Ga_{1-b}N (0≦b<a).

14. The semiconductor device as defined in claim 1 further comprising:
a second carrier supplying layer formed on said channel layer, said second carrier supplying layer having a electron affinity smaller than that of said carrier supplying layer.

15. The semiconductor device as defined in claim 14 wherein the second carrier supplying layer consists essentially of Al_{c}Ga_{1-c}N (0<y≦1).

16. The semiconductor device as defined in claim 15 wherein said buffer layer is thickest among layers formed on said substrate and consists essentially of Al_{y}Ga_{1-y}N (0<y≦1);
said channel layer consists essentially of GaN; and wherein
said carrier supplying layer consists essentially of AlₓGa₁₋ₓN (0<z<y).

17. The semiconductor device as defined in claim 1 wherein said carrier supplying layer has a thickness not larger than a critical film thickness of a layer thickest in film thickness among layers formed on said substrate.

18. The semiconductor device as defined in claim 14 further comprising:
a spacer layer interposed between said channel layer and said second carrier supplying layer, said spacer layer consisting essentially of a strain-free semiconductor of wultzite group III-V compound.

19. The semiconductor device as defined in claim 14 further comprising:
a source electrode and a drain electrode, formed on said second carrier supplying layer; and
a gate electrode formed in a region of said carrier supplying layer intermediate between said source electrode and the drain electrode.
